(19) United States
(12) Patent Application Publication
(10) Pub. No.: US 2026/0234804 A1
(43) Pub. Date: Aug. 13, 2026

(54) SUBSTRATE PROCESSING APPARATUS, SUBSTRATE PROCESSING METHOD, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventors: Yukinori ABURATANI, Toyama (JP); Hideharu ITATANI, Toyama (JP); Kaoru YAMAMOTO, Toyama (JP); Naofumi OHASHI, Toyama (JP)

(21) Appl. No.: 19/637,797

(22) Filed: Apr. 2, 2026

Related U.S. Application Data
(63) Continuation of application No. PCT/JP2024/011478, filed on Mar. 22, 2024.

(51) Int. Cl. C23C 16/52; C23C 16/04; C23C 16/44; C23C 16/455; C23C 16/458; C23C 16/46; H10P 14/43

(52) U.S. Cl. CPC C23C 16/52; C23C 16/042; C23C 16/4408; C23C 16/4412; C23C 16/45544; C23C 16/4584; C23C 16/46; H10P 14/43

(57) ABSTRACT

There is provided a technique that includes: a process vessel in which a first space and a second space located above the first space are provided; a mounting structure on which a substrate is placed; a driver configured to drive the mounting structure; a first supplier configured to control a supply of a first gas into the process vessel; a second supplier configured to control a supply of a second gas into the process vessel, wherein a molecular structure of the second gas is different from a molecular structure of the first gas; and a controller configured to be capable of controlling the driver, the first supplier and the second supplier to sequentially perform: (a) supplying the first gas to the substrate in the first space; (b) moving the substrate into the second space; and (c) supplying the second gas to the substrate in the second space.

### CROSS REFERENCE TO RELATED APPLICATIONS

This application is a bypass continuation application of PCT International Application No. PCT/JP2024/011478, filed on Mar. 22, 2024, in the WIPO, the entire contents of which are hereby incorporated by reference.

### TECHNICAL FIELD

The present disclosure relates to a substrate processing apparatus, a substrate processing method, a method of manufacturing a semiconductor device and a non-transitory computer-readable recording medium.

### BACKGROUND

### Related Art

According to some related arts, as a part of a substrate processing (that is, a manufacturing process of a semiconductor device), a gas (which is used to assist the substrate processing by modifying a surface of a substrate) and a gas (which is used to perform the substrate processing such as a film forming process of forming a film on the surface of the substrate) may be supplied to the substrate.

### SUMMARY

According to the present disclosure, there is provided a technique capable of suppressing an adhesion of foreign matters to a substrate.

According to the embodiments of the present disclosure, there is provided a technique that includes: a process vessel in which a first space and a second space located above the first space are provided; a mounting structure on which a substrate is placed; a driver configured to drive the mounting structure; a first supplier configured to control a supply of a first gas into the process vessel; a second supplier configured to control a supply of a second gas into the process vessel, wherein a molecular structure of the second gas is different from a molecular structure of the first gas; and a controller configured to be capable of controlling the driver, the first supplier and the second supplier to sequentially perform: (a) supplying the first gas to the substrate in the first space; (b) moving the substrate into the second space; and (c) supplying the second gas to the substrate in the second space.

### BRIEF DESCRIPTION OF THE DRAWINGS

FIG. 1 is a diagram schematically illustrating a vertical cross-section of a process vessel of a substrate processing apparatus according to one or more embodiments of the present disclosure, in a state where a wafer is set at a first position.

FIG. 2 is a diagram schematically illustrating a vertical cross-section of the process vessel of the substrate processing apparatus according to the embodiments of the present disclosure, in a state where the wafer is set at a second position.

FIG. 3 is a diagram schematically illustrating a gas supplier of the substrate processing apparatus according to the embodiments of the present disclosure.

FIG. 4 is a block diagram schematically illustrating a controller and its related components of the substrate processing apparatus according to the embodiments of the present disclosure.

FIG. 5 is a flow chart schematically illustrating a flow of a substrate processing according to the embodiments of the present disclosure.

FIG. 6 is a diagram schematically illustrating a vertical cross-section of a process vessel of the substrate processing apparatus according to other embodiments of the present disclosure.

### DETAILED DESCRIPTION

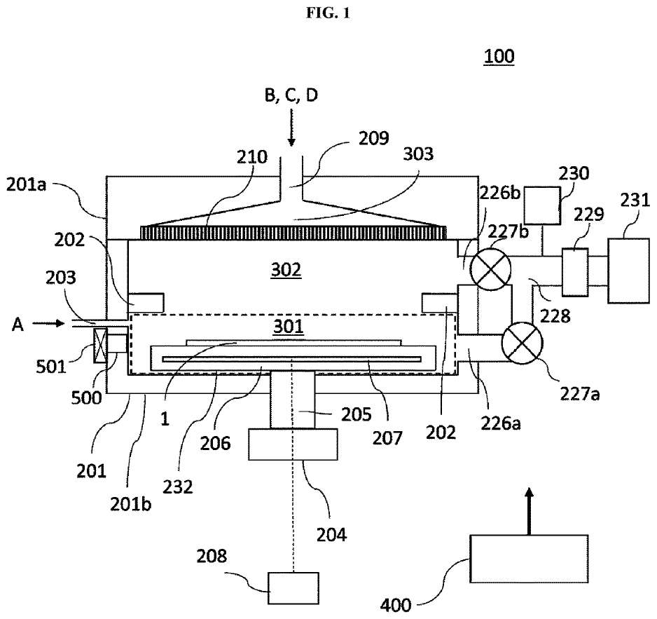

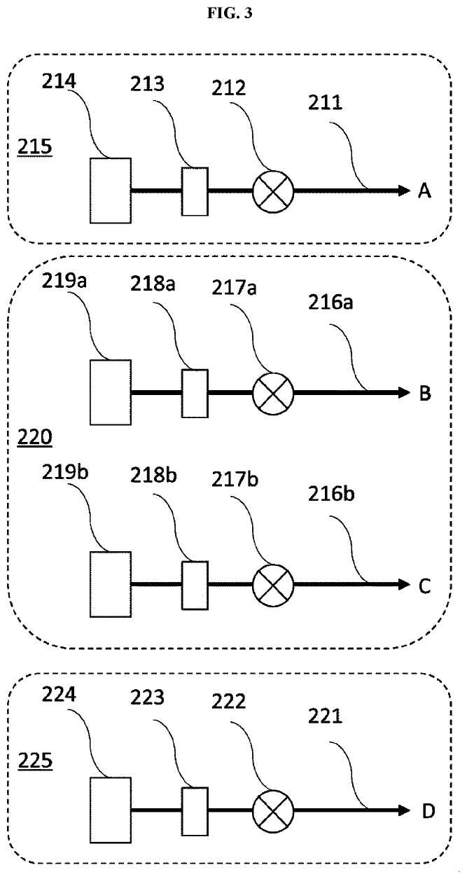

Hereinafter, one or more embodiments (also simply referred to as “embodiments”) according to the technique of the present disclosure will be described mainly with reference to FIGS. 1 to 6. In addition, the drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match. In addition, components substantially the same as those described with reference to FIG. 1 are given the same reference numerals, and redundant descriptions related thereto will be omitted. Further, the number of each component described in the present specification is not limited to one, and the number of each component may be two or more unless otherwise specified in the present specification.

### (1) Substrate Processing Apparatus

As shown in FIG. 1, a substrate processing apparatus 100 is provided with a process vessel 201. For example, the process vessel 201 is made of a metal material such as aluminum (Al) and stainless steel (SUS). In the process vessel 201 serving as a process chamber, a first space 301 (in which a wafer 1 serving as a substrate is processed with a first gas) and a second space 302 (in which the wafer 1 is processed with a second gas) are provided. The second space 302 is formed (provided) above the first space 301. A partition 202 is provided between the first space 301 and the second space 302. The process vessel 201 is constituted by an upper vessel 201a and a lower vessel 201b. Both of the first space 301 and the second space 302 are located in the lower vessel 201b.

A first gas supply hole (first supply structure) 203 and a substrate loading/unloading port 500 adjacent to a gate valve 501 are provided on a side surface of the first space 301 of the lower vessel 201b. The wafer 1 moves between the first space 301 and a transfer chamber (not shown) through the substrate loading/unloading port 500. In other words, the first space 301 also serves as a transfer space where the wafer 1 is transferred between an inside (inner portion) and an outside (outer portion) of the process vessel 201.

A substrate support (which is a substrate support structure) 232 configured to support the wafer 1 is located in the process vessel 201. The substrate support 232 mainly includes a substrate mounting table (which is a substrate placing table) 206 and a heater 207 serving as a heat source provided in the substrate mounting table 206. The substrate mounting table 206 may also be referred to as a “mounting structure”. A temperature of the heater 207 is controlled by a heater controller 208 serving as a temperature regulator (which is a temperature adjusting structure).

The substrate mounting table 206 is supported by a shaft 205. The shaft 205 penetrates a lower portion (bottom) of the process vessel 201, and is connected to an elevator (which is an elevating structure) 204 provided outside the process vessel 201. The elevator 204 serving as a driver (which is a driving structure) mainly includes: a support shaft capable of supporting the shaft 205; and an actuator configured to elevate, lower and rotate the support shaft. For example, the actuator is provided with: an elevator (not shown) including a motor configured to elevate and lower the support shaft; and a rotator (which is a rotating structure) (not shown) such as a gear configured to rotate the support shaft. By operating the elevator 204 to elevate and lower the shaft 205 and the substrate mounting table 206, it is possible to elevate or lower the wafer 1 placed (or mounted) on an upper surface (that is, on a substrate mounting surface which is a substrate placing surface) of the substrate mounting table 206.

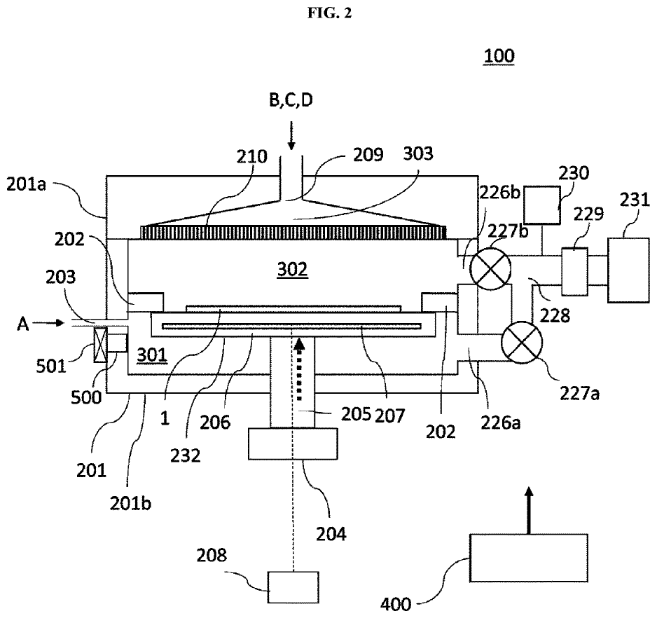

As shown in FIG. 1, when transferring the wafer 1, the substrate mounting table 206 is lowered to a first position where the substrate mounting surface faces the substrate loading/unloading port 500. At the first position, the wafer 1 is processed with the first gas. In addition, at the first position, the first space 301 and the second space 302 are not separated. When processing the wafer 1 with the second gas, the wafer 1 is elevated to the second position which is a processing position in the second space 302, as shown in FIG. 2. At the second position, the upper surface of the substrate mounting table 206 may abut against the partition 202 such that the first space 301 and the second space 302 are separated.

Above the second space 302 (that is, in the upper vessel 201a), a second gas supply hole (also referred to as a “second supply structure”) 209 is provided. The second gas and a third gas serving as a purge gas are supplied through the second supply structure 209 simultaneously or at different timings.

For example, a shower head 210 (which is in communication with the second supply structure 209 of the upper vessel 201a) is provided with a dispersion plate of a disk shape. A plurality of through-holes (which are in communication with the second gas supply holes) are provided at the dispersion plate. The dispersion plate is provided at a location facing the substrate mounting surface, and the through-holes are provided across an entirety of a surface of the dispersion plate. A buffer space 303 configured to diffuse a gas such as the second gas is provided between the dispersion plate and the second supply structure 209. The gas (second gas) supplied from the second supply structure 209 remains in the buffer space 303, and is then supplied to the second space 302 through the shower head 210 (the through-holes provided in the dispersion plate). Alternatively, the second supply structure 209 may include the shower head 210.

### (2) Gas Supplier

Subsequently, a gas supplier (which is a gas supply system) configured to supply various gases to the process vessel 201 will be described with reference to FIGS. 1, 2 and 3.

A molecular structure of the first gas is different from a molecular structure of the second gas. In the following description, one or both of a first source gas and a second source gas described later may be referred to as the “second gas”. In addition, in the following description, the third gas is an inert gas. An example will be described in which the third gas (inert gas) is used to purge the process vessel 201.

A first gas supply source 214, a mass flow controller (also simply referred to as an “MFC”) 213 serving as a flow rate controller and a valve 212 are sequentially installed at a first gas supply pipe 211 in this order from an upstream side to a downstream side of the first gas supply pipe 211 in a gas flow direction. The first gas supply pipe 211 is connected to the first supply structure 203 at a downstream side of the valve 212. A first supplier (which is a first supply system) 215 is constituted mainly by the first gas supply pipe 211, the MFC 213, the valve 212 and the first supply structure 203. The first supplier 215 may further include the first gas supply source 214. The first supplier 215 is configured to control a supply of the first gas into the process vessel 201 through the first supply structure 203.

A first source gas supply source 219a, an MFC 218a and a valve 217a are sequentially installed at a first source gas supply pipe 216a in this order from an upstream side to a downstream side of the first source gas supply pipe 216a in the gas flow direction. The first source gas supply pipe 216a is connected to the second supply structure 209 at a downstream side of the valve 217a. A first source gas supplier (which is a first source gas supply system) is constituted mainly by the first source gas supply pipe 216a, the MFC 218a, the valve 217a and the second supply structure 209. The first source gas supplier may further include the first source gas supply source 219a.

A second source gas supply source 219b, an MFC 218b and a valve 217b are sequentially installed at a second source gas supply pipe 216b in this order from an upstream side to a downstream side of the second source gas supply pipe 216b in the gas flow direction. The second source gas supply pipe 216b is connected to the second supply structure 209 at a downstream side of the valve 217b. A second source gas supplier (which is a second source gas supply system) is constituted mainly by the second source gas supply pipe 216b, the MFC 218b, the valve 217b and the second supply structure 209. The second source gas supplier may further include the second source gas supply source 219b.

In the following description, one or both of the first source gas supplier and the second source gas supplier may be referred to as a “second supplier 220” which is a second supply system. The second supplier 220 is configured to control a supply of the second gas into the process vessel 201 through the second supply structure 209.

A third gas supply source 224, a mass flow controller (MFC) 223 serving as a flow rate controller and a valve 222 are sequentially installed at a third gas supply pipe 221 in this order from an upstream side to a downstream side of the third gas supply pipe 221 in the gas flow direction. The third gas supply pipe 221 is connected to the second supply structure 209 at a downstream side of the valve 222. A third supplier (which is a third supply system) 225 is constituted mainly by the third gas supply pipe 221, the MFC 223, the valve 222 and the second supply structure 209. The third supplier 225 may further include the third gas supply source 224. The third supplier 225 is configured to control a supply of the third gas into the process vessel 201 through the second supply structure 209.

According to the present embodiments, an inert gas supplier (inert gas supply system) similar to the third supplier 225 may be connected to the first supply structure 203 such that the inert gas can be supplied through the first supply structure 203 into the first space 301.

### (3) Exhauster

An exhaust port 226a serving as a first exhaust port and an exhaust port 226b serving as a second exhaust port are provided at the lower vessel 201b of the process vessel 201. The exhaust port 226a is located on a side of the first space 301, and the exhaust port 226b is located on a side of the second space 302. Exhaust pipes connected to the exhaust port 226a and the exhaust port 226b are provided with valves 227a and 227b, respectively. The exhaust pipes are joined (merged) at downstream sides of the valves 227a and 227b to provide an exhaust pipe 228. In such a configuration, at least one among the valves 227a and 227b may be configured as a valve whose opening degree can be adjusted. By adjusting the opening degree of the valve, a magnitude relationship (between a conductance of the gas at a downstream side of the exhaust port 226a and a conductance of the gas at a downstream side of the exhaust port 226b) may be controlled.

In addition, at the exhaust pipe 228, an APC (Automatic Pressure Controller) 229 and a pressure monitor (which is a pressure monitoring structure) 230 are provided. The APC 229 is configured to control a pressure (inner pressure) of the process vessel 201 to a predetermined pressure. The APC 229 is provided with a valve structure (not shown) whose opening degree can be adjusted, and configured to adjust a conductance of the exhaust pipe 228 in response to an instruction from a controller 400 described later. An exhauster (which is an exhaust system) is constituted by the exhaust pipe 228, the pressure monitor 230, the valves 227a and 227b and the APC 229. The exhauster may further include a vacuum pump 231.

### (4) Controller

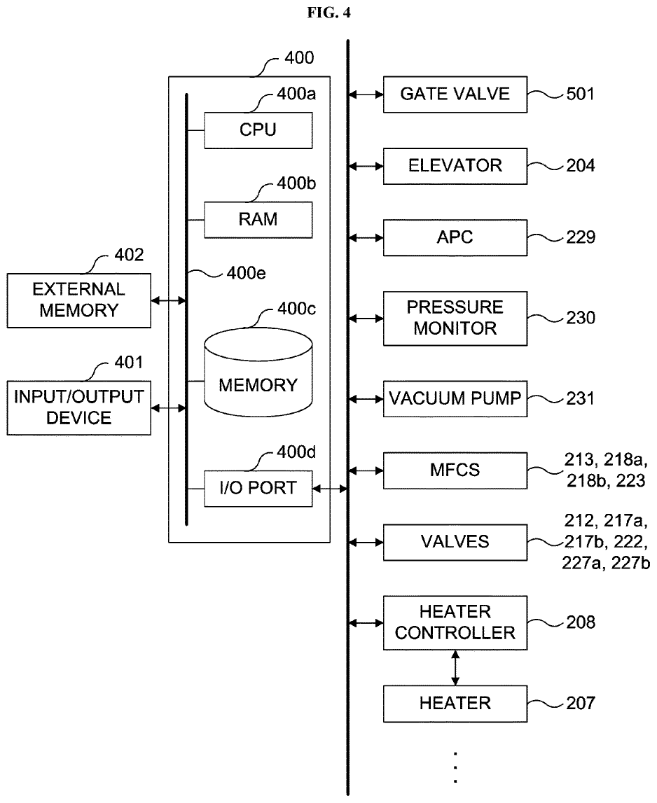

FIG. 4 is a block diagram schematically illustrating a control structure (that is, the controller 400) and its related components of the substrate processing apparatus 100. The controller 400 is constituted by a computer including a CPU (Central Processing Unit) 400a, a RAM (Random Access Memory) 400b, a memory 400c and an I/O port (input/output port) 400d. The RAM 400b, the memory 400c and the I/O port 400d are configured to be capable of communicating with the CPU 400a through an internal bus 400e. For example, an input/output device 401 (which is constituted by a component such as a touch panel) and an external memory 402 are connected to the controller 400.

For example, the memory 400c is configured by a component such as a flash memory and an HDD (Hard Disk Drive). For example, a control program configured to control operations of the substrate processing apparatus 100 and a process recipe (also simply referred to as a “recipe”) containing information on procedures (process procedures) and conditions (process conditions) of a substrate processing described later may be readably stored in the memory 400c. The recipe is obtained by combining steps (procedures) of the substrate processing described later such that the controller 400 can execute the steps to acquire a predetermined result, and is a high-level language compared to the control program. Hereinafter, the control program and the recipe may be collectively or individually referred to as a “program”. For example, the memory 400c is configured to sequentially store log information regarding operations and states of the apparatus (that is, the substrate processing apparatus 100). The RAM 400b functions as a memory area (work area) where a program or data read by the CPU 400a is temporarily stored. For example, the program or the data may be provided to the computer or the program or the data may be provided from the computer to an external apparatus by using a communication interface such as the Internet and a dedicated line, without using the external memory 402.

The I/O port 400d is connected to the components of the substrate processing apparatus 100, such as the gate valve 501, the elevator 204, the APC 229, the pressure monitor 230, the vacuum pump 231, the MFCs 213, 218a, 218b and 223, the valves 212, 217a, 217b, 222, 227a and 227b and the heater controller 208.

The CPU 400a is configured to read the control program from the memory 400c and execute the control program read from the memory 400c. In addition, the CPU 400a is configured to read the recipe for the wafer 1 from the memory 400c, for example, in accordance with an operation command inputted from the input/output device 401. In accordance with contents of the recipe read from the memory 400c, the CPU 400a may be configured to be capable of controlling various operations such as an opening and closing operation of the gate valve 501, an elevating and lowering operation of the elevator 204, an opening and closing operation of the APC 229, a pressure detecting operation by the pressure monitor 230, a control operation of turning on or off the vacuum pump 231, flow rate adjusting operations for various gases by the MFCs 213, 218a, 218b and 223, opening and closing operations of the valves 212, 217a, 217b, 222, 227a and 227b, and a temperature control operation of the heater 207 by the heater controller 208.

### (5) Substrate Processing Method

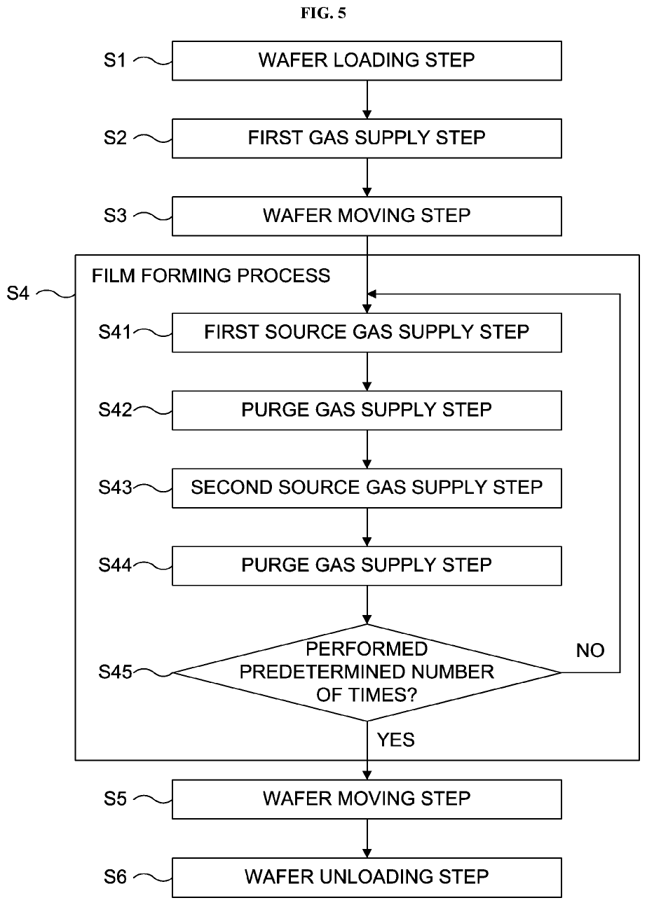

Hereinafter, an example of a substrate processing method of forming a film on the wafer 1 using the substrate processing apparatus 100, which serves as a part of a manufacturing process of a semiconductor device, will be described with reference to FIG. 5. In the following description, the operations of the components constituting the substrate processing apparatus 100 are controlled by the controller 400. In the substrate processing, for example, steps S1, S2, S3, S4, S5 and S6 are performed.

In the present specification, the term “wafer” may refer to “a wafer itself”, or may refer to “a wafer and a stacked structure (aggregated structure) of a predetermined layer (or layers) or a film (or films) formed on a surface of the wafer”. In the present specification, the term “a surface of a wafer” may refer to “a surface of a wafer itself”, or may refer to “a surface of a predetermined layer (or a predetermined film) formed on a wafer”. Thus, in the present specification, “forming a desired film (predetermined film) on a wafer” or “forming a film on a wafer” may refer to “forming a predetermined film directly on a surface of a wafer itself”, or may refer to “forming a predetermined film on a surface of another layer (or another film) formed on a wafer”. In the present specification, the terms “substrate” and “wafer” may be used as substantially the same meaning.

In the present specification, the term “supply amount” refers to a flow rate of the gas supplied related thereto, the term “pressure” refers to a pressure (inner pressure) of a reaction chamber (that is, the process chamber), and the term “process temperature” refers to a temperature of the wafer 1 or a temperature (inner temperature) of the process vessel 201.

### <Wafer Loading Step: S1>

As shown in FIG. 1, the substrate mounting table 206 is lowered to the first position, and the gate valve 501 is opened. Then, a transfer structure (not shown) places the wafer 1 onto the substrate mounting table 206 in the first space 301 through the substrate loading/unloading port 500.

After the wafer 1 is placed on the substrate mounting table 206, an electric power is supplied (applied) to the heater 207 installed in the substrate mounting table 206 to heat the wafer 1. In such an operation, by controlling an output of the heater 207 based on temperature information of the wafer 1 detected by a temperature sensor (not shown), it is possible to adjust the temperature of the wafer 1.

### <First Gas Supply Step: S2>

The first gas is supplied from the first supplier 215 to the wafer 1 in the first space 301 through the MFC 213, the valve 212 and the first supply structure 203. In such an operation, the exhauster is controlled such that the gas in the process vessel 201 is exhausted mainly (primarily) through the exhaust port 226a. After a predetermined time has elapsed from a start of the supply of the first gas, the valve 212 is closed. Thereby, the step S2 is completed. The supply of the first gas to a surface of the wafer 1 according to the present step (first gas supply step S2) may be performed a plurality number of times.

For example, process conditions of the present step are as follows:
A supply amount of the first gas: from 5 sccm to 1,000 sccm;
A pressure: from 133 Pa to 13,332 Pa; and
A process temperature: from 50° C. to 600° C.

In the present specification, a notation of a numerical range such as “from 5 sccm to 1,000 sccm” means that a lower limit and an upper limit are included in the numerical range. Therefore, for example, the numerical range “from 5 sccm to 1,000 sccm” means a range equal to or higher than 5 sccm and equal to or less than 1,000 sccm. The same also applies to other numerical ranges described in the present specification.

In the present step, the inert gas may be supplied into the second space 302 using the third supplier 225. In such a case, it is possible to form (or provide) a flow of the inert gas from an inside (inner portion) of the second space 302 to an inside (inner portion) of the first space 301. Thereby, it is possible to prevent (or suppress) the first gas from flowing into the second space 302, and it is also possible to prevent (or suppress) foreign matters (particles) generated due to the first gas from adhering to an inner wall of the lower vessel 201b.

For example, the first gas is an adsorption inhibiting gas capable of inhibiting an adsorption of the second gas onto the wafer 1. By supplying the first gas, it is possible to form a suppression layer (which is an inhibition layer) capable of inhibiting a formation of the film on at least a portion of the surface of the wafer 1. The first gas is selected depending on the film to be formed in a film forming process described later. For example, when titanium tetrachloride (TiCl₄) gas is used as the first source gas, a halide gas containing fluorine (such as tungsten hexafluoride (WF₆) gas) may be used as the first gas.

As the inert gas, for example, a gas such as N₂ gas, helium (He) gas, neon (Ne) gas, and argon (Ar) gas may be used.

For example, the suppression layer may be formed preferentially on an opening side (opening portion) of a recess (which is a concave structure) formed on the wafer 1 as compared with a deeper side (deeper portion) of the recess. In such a case, in the film forming process, it is possible to suppress the formation of the film on the opening side of the recess and it is also possible to promote the formation of the film on the deeper side of the recess. It is also possible to form the film so as to fill at least a part of the recess (that is, it is possible to perform a “gap-fill” operation).

In addition, for example, the suppression layer may be formed preferentially on a surface (predetermined surface) of a predetermined material formed on the wafer 1, rather than on the other surfaces. In such a case, it is possible to form the film preferentially on the other surfaces relative to the predetermined surface.

In the step S2, the suppression layer may be formed not only on the surface of the wafer 1, but also on at least a part of a surface of an object (for example, the inner wall of the lower vessel 201b, a lower surface of the substrate mounting table 206 or the shaft 205) in the first space 301. Thereby, when the second gas used in the formation of the film in the second space 302 flows into the first space 301 as described later, it is possible to suppress a reaction caused by the second gas on the surface of the object in the first space 301.

In the step S2, it is preferable that the gas in the process vessel 201 is exhausted from the process vessel 201 mainly (primarily) through the exhaust port 226a. For example, it is preferable to open the valve 227a and close the valve 227b such that the gas is not exhausted through the exhaust port 226b. Alternatively, it is preferable that the conductance of the gas at the downstream side of the exhaust port 226a is set to be greater than the conductance of the gas at the downstream side of the exhaust port 226b. In such a case, the first gas supplied into the first space 301 is less likely to flow into the second space 302. Thereby, it is possible to prevent (or suppress) the foreign matters generated due to the first gas from adhering to the inner wall of the lower vessel 201b.

In the present step, the controller 400 preferably controls the exhauster and various gas suppliers such that a pressure (inner pressure) of the second space 302 is set to be higher than a pressure (inner pressure) of the first space 301. In such a case, the first gas is less likely to flow into the second space 302. Thereby, it is possible to further prevent (or suppress) the foreign matters due to the first gas from adhering to the inner wall of the lower vessel 201b.

For example, consider a case where the temperature of the wafer 1 in the step S2 is set to be lower than the temperature of the wafer 1 in the step S4 described later. When the wafer 1 is at a low temperature, the gas used in the present embodiments tends to adhere more easily to the surface of the wafer 1. Thereby, it is possible to enhance an effect of the adsorption inhibiting gas. However, in the step S4, the inner temperature of the second space 302 is more likely to be higher than in the step S2. Thereby, the first gas adsorbed to an object in the second space 302 is more likely to be desorbed. As a result, the foreign matters generated due to the first gas (that is, the foreign matters caused by the first gas) are more likely to be generated. According to the technique of the present disclosure, the first gas and the second gas are supplied to the wafer 1 in the first space 301 and the second space 302, respectively. Therefore, even in such a case, it is possible to effectively suppress an intrusion of the foreign matters into the wafer 1.

After the supply of the first gas in the step S2 is completed, the inert gas may be supplied into the process vessel 201 using the third supplier 225 and exhausted through one or both of the exhaust port 226a and the exhaust port 226b. Thereby, since the process vessel 201 is purged, it is possible to suppress a migration of the first gas (and the foreign matters generated due to the first gas) remaining in the process vessel 201 into the second space 302, and it is also possible to suppress a stagnation of the first gas (and the foreign matters) therein.

In addition, after the supply of the first gas in the step S2 is completed, the inert gas may be supplied into the first space 301 through the first supply structure 203 and exhausted through one or both of the exhaust port 226a and the exhaust port 226b. Thereby, since the first space 301 is purged, the first gas remaining in the process vessel 201 is less likely to move to the second space 302.

### <Wafer Moving Step: S3>

The elevator 204 elevates the substrate mounting table 206 to move the wafer 1 to the second space 302. In such an operation, it is preferable to open the valve 227a and the valve 227b to exhaust the gas in the process vessel 201. Thereby, it is possible to suppress the migration of the first gas (and the foreign matters generated due to the first gas) remaining in the process vessel 201 into the second space 302, and it is also possible to suppress the stagnation of the first gas (and the foreign matters) therein. In the present step, it is preferable that the inert gas is supplied through the first supply structure 203 into the process vessel 201. Thereby, the first gas remaining in the process vessel 201 is less likely to move to the second space 302.

According to the present embodiments, the partition 202 is configured to overlap with the substrate mounting table 206 when viewed from a direction in which the substrate mounting table 206 is moved. Therefore, the substrate mounting table 206 is elevated to a position (that is, a position shown in FIG. 2) where a part of the substrate mounting table 206 overlaps with the partition 202 provided in the lower vessel 201b. Thereby, it is possible to prevent the first gas (and the foreign matters generated due to the first gas) remaining in the first space 301 from flowing into the second space 302.

### <Film Forming Process: S4>

Subsequently, by performing steps S41, S42, S43 and S44 sequentially, the step S4 serving as the film forming process (also referred to as a “second gas supply step” or a “second gas process”) is performed.

According to the present embodiments, in the step S4, the exhauster is controlled such that the gas in the process vessel 201 is exhausted mainly (primarily) through the exhaust port 226b. For example, it is preferable to open the valve 227b and close the valve 227a. Alternatively, it is preferable that the conductance of the gas at the downstream side of the exhaust port 226b is set to be greater than the conductance of the gas at the downstream side of the exhaust port 226a. In such a case, the second gas supplied into the second space 302 is less likely to flow into the first space 301. Thereby, it is possible to prevent (or suppress) the film from being formed in the first space 301.

In addition, in the step S4, the inert gas may be supplied into the first space 301 through the first supply structure 203. In such a case, it is possible to form (or provide) a flow of the inert gas from the first space 301 to the second space 302. Thereby, it is possible to suppress a flow of the second gas from the second space 302 toward the first space 301.

### <First Source Gas Supply Step: S41>

The first source gas (the second gas) is supplied to the wafer 1 through the first source gas supply pipe 216a. In such an operation, the first source gas is selectively adsorbed to the wafer 1 except for the portion of the surface of the wafer 1 where the suppression layer is formed by the first gas. In such an operation, the inert gas may be supplied through the third supplier 225. After a predetermined time has elapsed from a start of the supply of the first source gas, the valve 217a is closed. Thereby, the step S41 is completed. As the first source gas, for example, the titanium tetrachloride (TiCl₄) gas may be used.

### <Purge Gas Supply Step: S42>

After the step S41 is completed, with the valve 227b open or with both of the valves 227a and 227b open, the gas in the second space 302 (or the process vessel 201) is exhausted, and the inert gas is supplied through the third supplier 225 to purge the process vessel 201. Thereby, it is possible to remove the first source gas (and foreign matters generated due to the first source gas) remaining in the second space 302 from the second space 302.

### <Second Source Gas Supply Step: S43>

Subsequently, the second source gas (the second gas) is supplied to the wafer 1 through the second source gas supply pipe 216b. In such an operation, the first source gas adsorbed on the wafer 1 reacts with the second source gas to form a desired film. The inert gas may also be supplied through the third supplier 225 simultaneously with the second source gas. After a predetermined time has elapsed from a start of the supply of the second source gas, the valve 217b is closed. Thereby, the step S43 is completed. As the second source gas supplied in the present step, for example, ammonia (NH₃) gas may be used. In such a case, when the first source gas is the TiCl₄ gas, a titanium nitride film (TiN film) is formed.

### <Purge Gas Supply Step: S44>

After the step S43 is completed, with the valve 227b open or with both of the valves 227a and 227b open, the gas in the second space 302 (or the process vessel 201) is exhausted, and the inert gas is supplied through the third supplier 225 to purge the process vessel 201. Thereby, it is possible to remove the second source gas (which is unreacted) and reaction by-products from the second space 302.

### <Performing Cycle Predetermined Number of Times: S45>

By performing a cycle including the steps S41, S42, S43 and S44 a predetermined number of times (n times, where n is an integer of 1 or more), it is possible to form a film of a desired thickness.

In the step S4, as described above, a part of the substrate mounting table 206 overlaps with the partition 202. Thereby, the second space 302 is isolated from the first space 301 in the first gas supply step S2. As a result, it is possible to prevent the first gas and the foreign matters generated due to the first gas remaining therein from adhering to a surface of the film and the inner wall of the lower vessel 201b in the second space 302 during the film forming process S4 being performed in the second space 302. In addition, since the first space 301 is isolated (or blocked), it is possible to efficiently exhaust the first gas and the foreign matters generated due to the first gas remaining therein.

For example, process conditions of the film forming process S4 (when supplying the first source gas and when supplying the second source gas) are as follows:
A supply amount: from 100 sccm to 1,000 sccm;
A pressure: from 1,333 Pa to 13,332 Pa; and
A process temperature: from 50° C. to 600° C.

After the step S4, with the valve 227b open or with both of the valves 227a and 227b open, the gas in the second space 302 (or the process vessel 201) is exhausted. Thereby, it is possible to remove the gas (which is unreacted) and the reaction by-products remaining in the process vessel 201 from the process vessel 201. In addition, with the valve 222 open, the inert gas is supplied into the process vessel 201. For example, a purge may be performed simultaneously with or after the step S5, as described below.

### <Wafer Moving Step: S5>

The elevator 204 lowers the substrate mounting table 206. Thereby, the wafer 1 is moved to the first space 301.

### <Wafer Unloading Step: S6>

The gate valve 501 is opened. Then, the transfer structure (not shown) unloads (transfers) the wafer 1 from the process vessel 201 through the substrate loading/unloading port 500.

According to the present embodiments, it is possible to obtain one or more of the following effects, in addition to effects mentioned above.

When the surface of the wafer 1 is modified using the first gas and then the wafer 1 is processed using the second gas in the same process vessel 201, the first gas may adhere to an object in the process vessel 201 (for example, an inside of a supply structure such as the first supply structure 203, the inner wall of the lower vessel 201b and the lower surface of the substrate mounting table 206). When the second gas is supplied to the wafer 1 in such a state, components derived from the first gas may be contained in the film. In addition, due to an action of the first gas, the film formed on the surface of the object in the process vessel 201 may be peeled off, and the film peeled off may adhere to the surface of the wafer 1. In other words, due to a generation of the foreign matters, a yield of the substrate processing may be reduced.

After the first gas is supplied to the wafer in the first space 301, the second gas is supplied to the wafer in the second space 302 above the first space 301. Thereby, it is possible to prevent (or suppress) the first gas from adhering to the surface of the object in the second space 302. Therefore, it is possible to prevent (or suppress) the first gas and the foreign matters generated due to the first gas from adhering to the wafer 1.

A circulation (flow) of the gas between the first space 301 and the second space 302 is restricted (or suppressed) by the partition 202. Thereby, the first gas in the first space 301 is less likely to flow into the second space 302. Therefore, the first gas (and the foreign matters generated due to the first gas) remaining in the first space 301 is less likely to adhere to the inner wall of the lower vessel 201b of the second space 302 and to the wafer 1 when the film forming process S4 is being performed.

In addition, the second space 302 is located above the first space 301. Thereby, even when the space in which the step S2 is performed and the space in which the step S4 is performed are separated, it is possible to suppress an increase in an area (footprint) occupied by the substrate processing apparatus 100, in the horizontal direction.

The embodiments mentioned above are described by way of an example in which the WF₆ gas is used as the first gas. However, the technique of the present disclosure is not limited thereto. For example, the technique of the present disclosure may also be applied when a gas such as chlorine trifluoride (ClF₃) gas, nitrogen trifluoride (NF₃) gas, hydrogen fluoride (HF) gas, and fluorine (F₂) gas is used as the first gas.

Similarly, the embodiments mentioned above are described by way of an example in which the TiCl₄ gas is used as the first source gas in the second gas supply step (that is, the film forming process). However, the technique of the present disclosure is not limited thereto. For example, the technique of the present disclosure may also be applied when a gas such as a halogen-containing gas is used as the first source gas. As the halogen-containing gas, for example, a gas such as silicon tetrachloride (SiCl₄), aluminum tetrachloride (AlCl₄), zirconium tetrachloride (ZrCl₄), hafnium tetrachloride (HfCl₄), tantalum pentachloride (TaCl₅), tungsten pentachloride (WCl₅), molybdenum pentachloride (MoCl₅) and tungsten hexachloride (WCl₆) may be used.

Similarly, the embodiments mentioned above are described by way of an example in which the NH₃ gas is used as the second source gas in the second gas supply step (that is, the film forming process). However, the technique of the present disclosure is not limited thereto. For example, the technique of the present disclosure may also be applied when a gas reacting with the first source gas is used as the second source gas. As the gas reacting with the first source gas (that is, as a reactive gas reacting with the first source gas), for example, a gas such as hydrazine (N₂H₄), water (H₂O), oxygen (O₂) and a gaseous mixture of hydrogen (H₂) and O₂ may be used.

### Modified Example

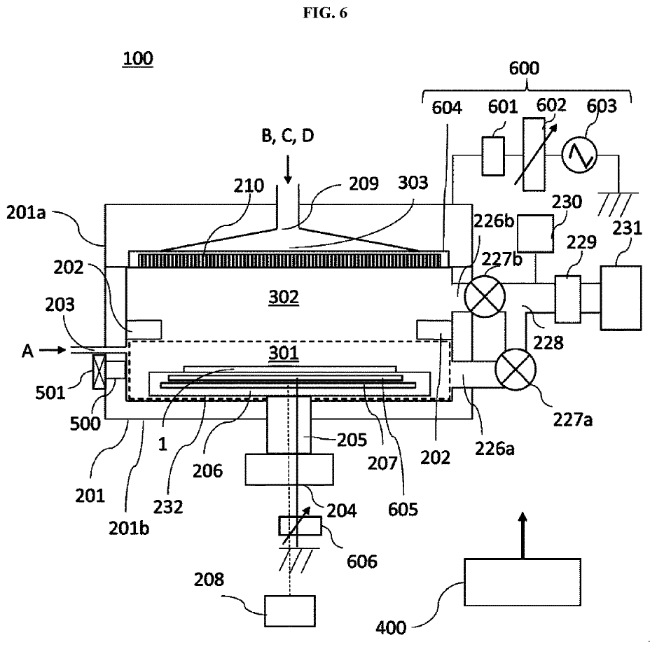

A substrate processing apparatus according to a modified example will be described with reference to FIG. 6. According to a modified example, the substrate processing apparatus is provided with a plasma generator (which is a plasma generating structure) configured to activate the second gas (that is, one or both of the first source gas and the second source gas) in the second space 302 by a potential difference with the substrate mounting table 206. Other configuration of the substrate processing apparatus according to the modified example are substantially the same as those of the substrate processing apparatus 100 according to the embodiments mentioned above.

As an activator (which is an activating structure) 600 serving as the plasma generator capable of supplying an electromagnetic wave (a high frequency power or a microwave), a matcher (which is a matching structure) 602 and a high frequency power supply 603 are connected to an electrode 604 provided in the upper vessel 201a. The electrode 604 is configured to generate a capacitively coupled plasma. A bias electrode 605 in the substrate mounting table 206 is connected to a bias regulator (which is a bias adjusting structure) 606. It is possible to adjust the bias by the bias regulator 606. For example, an impedance meter 601 may be provided between the electrode 604 of the activator 600 and the high frequency power supply 603.

In addition, the high frequency power supply 603, the matcher 602 and the impedance meter 601 can transmit and receive information to and from the controller 400. The controller 400 is configured to control the high frequency power supply 603 and the matcher 602 based on a value measured by the impedance meter 601.

According to the present modified example, it is also possible to obtain substantially the same effects as in the embodiments mentioned above. In addition, according to the present modified example, a source gas (that is, the second gas such as the first source gas and the second source gas) is decomposed into a plasma state, activated, and then reacted. Thereby, it is possible to uniformly form the film with a sufficient (or good) coverage over a detailed structure on the surface of the wafer 1. In addition, it is possible to set the process temperature to be low. Thereby, it is possible to suppress an effect of the process temperature on the surface of the wafer 1.

In such a case, since a voltage is applied between the upper vessel 201a and the substrate mounting table 206, it is preferable that the substrate mounting table 206 does not come into contact with objects (for example, the partition 202) other than the shaft 205. Therefore, in the step S4, the second gas flows into the first space 301, and a film forming reaction is likely to occur in the first space 301. According to the technique of the present disclosure, in the step S2, simultaneously with forming the suppression layer on the wafer 1, it is possible to form the suppression layer on the surface of the object (for example, the inner wall of the lower vessel 201b and the gate valve 501) in the first space 301. Therefore, it is possible to suppress the generation of the foreign matters in the first space 301.

The embodiments mentioned above and the modified example mentioned above may be appropriately combined. The process procedures and the process conditions of each combination thereof may be substantially the same as those of the embodiments mentioned above or the modified example mentioned above.

The embodiments mentioned above and the modified example mentioned above are described by way of an example in which the step S2 (which serves as an adsorption inhibiting step of supplying the adsorption inhibiting gas serving as the first gas) is performed before the step S4 (that is, the film forming process). However, the technique of the present disclosure may be preferably applied when an adsorption assisting gas capable of assisting an adsorption of the first source gas (which is a part of the second gas to be supplied later) is supplied as the first gas in the step S2. The adsorption assisting gas assists the adsorption of the first source gas to be supplied later onto at least a part of the surface of the wafer 1. In other words, it is possible to assist the formation of the film on at least a part of the surface of the wafer 1 (that is, it is possible to selectively form the film). In addition, since the adsorption assisting gas assists the formation of the film by the source gas (that is, the first source gas) in the film forming step, the adsorption assisting gas may also be referred to as a “film formation assisting gas”.

For example, in the step S4, one of the step S42 and the step S44 may be omitted. That is, the first source gas alone or the second source gas alone may be supplied into the second space 302 to process the wafer 1. For example, in the step S4, the step S43 may be performed at least partially simultaneously with the step S41. That is, the first source gas and the second source gas may be simultaneously supplied at least partially into the second space 302 to process the wafer 1. Even in such a case, it is also possible to obtain substantially the same effects as the embodiments mentioned above.

For example, the embodiments mentioned above are described by way of an example in which a single wafer type substrate processing apparatus capable of processing one or several substrates at once is used to form the film. However, the technique of the present disclosure is not limited thereto. For example, the technique of the present disclosure may be preferably applied when a batch type substrate processing apparatus capable of simultaneously processing a plurality of substrates is used to form the film. In addition, the technique of the present disclosure may be preferably applied regardless of whether such a substrate processing apparatus is provided with a hot wall type process furnace or a cold wall type process furnace.

The process procedures and the process conditions of each process using the substrate processing apparatuses exemplified above may be substantially the same as those of the embodiments mentioned above. Even in such a case, it is possible to obtain substantially the same effects as in the embodiments mentioned above.

According to some embodiments of the present disclosure, it is possible to suppress the adhesion of the foreign matters to the substrate.

What is claimed is:

1. A substrate processing apparatus comprising:
a process vessel in which a first space and a second space located above the first space are provided;
a mounting structure on which a substrate is placed;
a driver configured to drive the mounting structure;
a first supplier configured to control a supply of a first gas into the process vessel;
a second supplier configured to control a supply of a second gas into the process vessel, wherein a molecular structure of the second gas is different from a molecular structure of the first gas; and
a controller configured to be capable of controlling the driver, the first supplier and the second supplier to sequentially perform:
(a) supplying the first gas to the substrate in the first space;
(b) moving the substrate into the second space; and
(c) supplying the second gas to the substrate in the second space.

2. The substrate processing apparatus of claim 1, wherein the first supplier comprises a first supply structure provided in the first space and the second supplier comprises a second supply structure provided in the second space, and
wherein the controller is further configured to be capable of controlling the first supplier such that the first gas is supplied in (a) through the first supply structure and controlling the second supplier such that the second gas is supplied in (c) through the second supply structure.

3. The substrate processing apparatus of claim 1, further comprising:
an exhauster; and
a first exhaust port communicating between the first space and the exhauster,
wherein the controller is further configured to be capable of controlling the exhauster such that the first gas is exhausted in (a) through the first exhaust port.

4. The substrate processing apparatus of claim 3, further comprising:
a second exhaust port communicating between the second space and the exhauster and different from the first exhaust port,
wherein the controller is further configured to be capable of controlling the exhauster such that the first gas is exhausted in (b) through the second exhaust port.

5. The substrate processing apparatus of claim 4, wherein the controller is further configured to be capable of controlling the exhauster such that an inner pressure of the second space in (a) is set to be higher than an inner pressure of the first space in (a).

6. The substrate processing apparatus of claim 4, wherein the controller is further configured to be capable of controlling the exhauster such that:
(i) a conductance of the first gas downstream of the first exhaust port in (a) is greater than a conductance of the first gas downstream of the second exhaust port; or
(ii) the first gas is not exhausted through the second exhaust port in (a).

7. The substrate processing apparatus of claim 4, wherein the controller is further configured to be capable of controlling the exhauster such that the first gas is exhausted through the second exhaust port in (a).

8. The substrate processing apparatus of claim 1, further comprising:
a third supplier configured to supply a purge gas into the second space,
wherein the controller is further configured to be capable of controlling the third supplier such that the purge gas is supplied into the second space in (a).

9. The substrate processing apparatus of claim 1, further comprising:
a temperature regulator configured to control a temperature of the substrate,
wherein the controller is further configured to be capable of controlling the temperature regulator such that the temperature of the substrate in (a) is lower than the temperature of the substrate in (b).

10. The substrate processing apparatus of claim 1, further comprising:
a loading/unloading port provided in the first space and configured such that the substrate is movable between an inside and an outside of the process vessel through the loading/unloading port.

11. The substrate processing apparatus of claim 1, further comprising:
a partition configured to restrict a gas flow between the first space and the second space.

12. The substrate processing apparatus of claim 11, wherein the partition is configured to overlap with a part of the mounting structure when viewed from a direction in which the mounting structure is driven.

13. The substrate processing apparatus of claim 1, wherein, in (a), a suppression layer capable of inhibiting a progress of a processing by the second gas in (b) is formed on at least a part of a surface of the substrate.

14. The substrate processing apparatus of claim 13, wherein, in (a), the suppression layer is further formed on at least a part of a surface of an object in the first space.

15. The substrate processing apparatus of claim 1, wherein the first supplier is provided with a supply structure located at a position facing a surface of the substrate.

16. The substrate processing apparatus of claim 1, wherein the mounting structure is configured to be capable of supporting the substrate and one or more substrates mounted thereon.

17. The substrate processing apparatus of claim 1, further comprising:
an activator configured to activate the second gas in the second space by changing a potential difference between the mounting structure and a structure other than the mounting structure.

18. A substrate processing method comprising:
(a) supplying a first gas to a substrate in a first space in a process vessel;
(b) moving the substrate into a second space in the process vessel, wherein the second space is located above the first space in the process vessel; and
(c) supplying a second gas to the substrate in the second space, wherein a molecular structure of the second gas is different from a molecular structure of the first gas,
wherein (a), (b) and (c) are performed sequentially.

19. A method of manufacturing a semiconductor device, comprising the method of claim 18.

20. A non-transitory computer-readable recording medium storing a program that causes, by a computer, a substrate processing apparatus to perform:
(a) supplying a first gas to a substrate in a first space in a process vessel;
(b) moving the substrate into a second space in the process vessel, wherein the second space is located above the first space in the process vessel; and
(c) supplying a second gas to the substrate in the second space, wherein a molecular structure of the second gas is different from a molecular structure of the first gas,
wherein (a), (b) and (c) are performed sequentially.
